(19) United States
(12) Patent Application Publication
(10) Pub. No.: US 2013/0110421 A1
(43) Pub. Date: May 2, 2013

(54) DEVICE ANALYSIS

(71) Applicant: Kay Lederer, Dresden (DE)

(72) Inventor: Kay Lederer, Dresden (DE)

(73) Assignee: PLASTIC LOGIC LIMITED, Cambridge (GB)

(21) Appl. No.: 13/696,157

(22) PCT Filed: May 6, 2011
(86) PCT No.: PCT/EP11/57354

§ 371 Date: Dec. 21, 2012

(30) Foreign Application Priority Data
May 7, 2010 (GB) 1007665.1

(51) Int. Cl. G01R 31/28; G06F 15/00; G01N 23/201

(52) U.S. Cl. CPC G01R 31/28; G01N 23/201; G06F 15/00
USPC 702/57; 702/189

(57) ABSTRACT

Performing an analysis of an electronic device sample by measuring a property at a plurality of points of said electronic device sample, and in advance of said analysis subjecting said plurality of points to at least one treatment that increases the difference in said property between at least two elements of said electronic device sample.

The present invention relates to a technique for analysing an electronic device.

For the purpose of, for example, analysing the cause of device failures or assessing the quality of a production process, it can be useful to investigate the microstructure of the inner portion of an electronic device.

It is an aim of the present invention to provide a technique for facilitating such investigation.

The present invention provides a method, comprising: performing an analysis of an electronic device sample by measuring a property at a plurality of points of said electronic device sample, and in advance of said analysis subjecting said plurality of points to at least one treatment that increases the difference in said property between at least two elements of said electronic device sample.

In one embodiment, said property is selected from the group consisting of: a mechanical property; a physical property; a chemical property and an electrical property.

In one embodiment, said analysis is performed by a technique selected from the group consisting of: scanning electron microscopy, transmission electron microscopy and atomic force microscopy.

In one embodiment, said at least two elements are at least two layers of a stack of layers.

In one embodiment, said electronic device comprises a stack of layers, and said treatment comprises cutting through said stack of layers in a way that generates a difference in surface morphology at the cut surface between at least two of said layers of the stack.

In one embodiment, said treatment is a chemical treatment.

In one embodiment, said property is electron scattering intensity, and said chemical treatment increases the contrast in electron scattering intensity between said at least two elements.

In one embodiment, the method further comprises preparing said electronic device sample by exposing an inner portion of said electronic device.

In one embodiment, said electronic device comprises an array of thin film transistors.

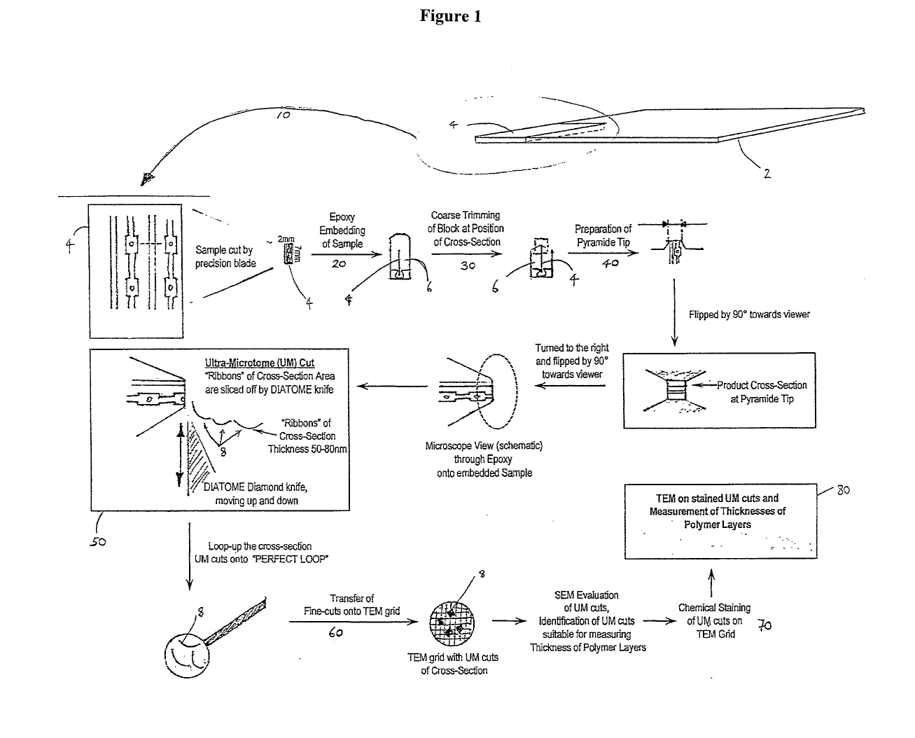

Embodiments of the present invention are described hereunder, by way of example only, with reference to FIG. 1 which illustrates a method in accordance with an embodiment of the present invention.

From an organic electronic device 2, such as, for example, an organic thin film transistor display, organic light-emitting diode or organic solar cell comprising a stack of layers including one or more polymer layers is cut a small sample section 4 using a sharp scalpel knife, a saw or stencil (STEP 10). The sample section 4 has a length and width of a few millimetres.

The sample section 4 is then embedded (STEP 20) into an epoxy resin polymer matrix 6 as the first stage of an ultra-microtomy technique. Where a cryo-ultramicrotomy technique is to be used, an acrylate can be used for the polymer matrix in which the sample section 4 is embedded. For suitable samples, microtoming without embedding is also possible.

Next, the epoxy block containing the embedded sample section 4 is subject to coarse trimming (STEP 30) using a trimming device to expose a cross-sectional surface of the sample section 4, followed by further processing (STEP 40) to prepare a pyramid tip at the exposed surface.

Next, an oscillating diamond knife is used to slice thin cross sections (lamellae) 8 of e.g. about 20-150 nm thickness from the pyramid tip (STEP 50).

These ultra-thin cross section lamellae 8 are transparent to the electron beam of an electron microscope.

In order to enhance the contrast between the different organic, polymeric or polymer composite layers in the organic electronic device, these ultra-thin cross section lamellae 8 are subsequently chemically treated (staining—STEP 70) to enhance the contrast between layers in a transmission electron microscopy (TEM) image. In other words, the lamellae 8 are chemically treated so as to increase the differences in the electron scattering properties between the different layers of the electronic device. The thus chemically-treated lamellae are then subject to TEM to produce high resolution images from which at least two different organic layers in the organic electronic device and the interface(s) between those organic layers can be clearly identified (STEP 80).

The electron scattering intensity of a material generally depends on the number of electrons in the atoms that constitute the material, (i.e. it depends on the atomic number of the atoms that make up the material). Organic materials, polymers or polymer composites of the kind used in electronic devices are composed mainly of the elements carbon C and hydrogen H, and the electron scattering intensities of such materials are generally very similar. Without some treatment to increase the difference in electron scattering intensity between the layers, it can be difficult to distinguish between the layers in an electron microscopy image.

According to this embodiment of the invention, the lamellae 8 are chemically treated with a chemical agent that selectively incorporates relatively high atomic number atoms into one or more (but not all) of the layers and interfaces that make up the lamellae 8. Examples of useful chemical agents are compounds like chlorosulfonic acid, hydrazine, phosphotungstic acid and heavy metal compounds such as RuO₄, RuCl₃ , NaClO, OsO₄, Uranylacetate or Iodine.

According to one variation of the above-described embodiment, a focused ion beam technique is used to produce the lamellae instead of a diamond knife. With a focused ion beam technique, ultra-thin cross-sectional lamellae 8 can be produced directly from the sample section 4 or the organic electronic device 2, without the need for any preparatory cutting, embedding or trimming steps.

According to another variation, the same kind of chemical treatment can be used to enhance the contrast between layers in a scanning electron microscope (SEM) image.

According to another embodiment of the present invention, advantage is made use of differences in mechanical properties such as hardness, stiffness, elasticity etc. between the organic, polymer and/or polymer composite layers in the electronic device. The embedded sample section (ultra-microtome) is cut through at a cutting angle and/or cutting speed at which these differences in mechanical properties between the layers manifest themselves as differences in surface morphology between the layers at the exposed cut surface. Differences in surface morphology are clearly identifiable in an SEM or Atomic Force Microscopy (AFM) image of the exposed surface, and the technique therefore facilitates the visualization of the different layers that make up the electronic device and the interfaces therebetween.

The techniques described above facilitate the visualization of different organic layers in an electronic device and the interfaces therebetween. Layer thicknesses can be measured to a high degree of accuracy, and the location and quality of interfaces can be better investigated.

The above-described techniques are of particular use in organic and polymer electronic devices containing of stacks of organic material layers and/or combinations of organic material layers with inorganic material layers.

In addition to any modifications explicitly mentioned above, it will be evident to a person skilled in the art that various other modifications of the described embodiment may be made within the scope of the invention.

1.-9. (canceled)

10. A method, comprising:
performing an analysis of an electronic device sample by measuring a property at a plurality of points of said electronic device sample, and
in advance of said analysis subjecting said plurality of points to at least one treatment that increases the difference in said property between at least two elements of said electronic device sample.

11. A method according to claim 10, wherein said property is selected from the group consisting of: a mechanical property; a physical property; a chemical property and an electrical property.

12. A method according to claim 10, wherein said analysis is performed by a technique selected from the group consisting of: scanning electron microscopy, transmission electron microscopy and atomic force microscopy.

13. A method according to claim 10, wherein said at least two elements are at least two layers of a stack of layers.

14. A method according to claim 13, wherein said electronic device comprises a stack of layers, and said treatment comprises cutting through said stack of layers in a way that generates a difference in surface morphology at the cut surface between at least two of said layers of the stack.

15. A method according to claim 10, wherein said treatment is a chemical treatment.

16. A method according to claim 15, wherein said property is electron scattering intensity, and said chemical treatment increases the contrast in electron scattering intensity between said at least two elements.

17. A method according to claim 10, comprising preparing said electronic device sample by exposing an inner portion of said electronic device.

18. A method according to claim 10, wherein said electronic device comprises an array of thin film transistors.
